(19) United States
(12) Patent Application Publication
(10) Pub. No.: US 2013/0099252 A1
(43) Pub. Date: Apr. 25, 2013

(54) METHOD OF MANUFACTURING SILICON CARBIDE SUBSTRATE AND SILICON CARBIDE SUBSTRATE

(71) Applicant: SUMITOMO ELECTRIC INDUSTRIES, LTD., Osaka (JP)

(72) Inventor: Makoto SASAKI, Itami-shi (JP)

(73) Assignee: SUMITOMO ELECTRIC INDUSTRIES, LTD., Osaka (JP)

(21) Appl. No.: 13/655,006

(22) Filed: Oct. 18, 2012

Related U.S. Application Data
(60) Provisional application No. 61/550,524, filed on Oct. 24, 2011.

(30) Foreign Application Priority Data
Oct. 24, 2011 (JP) 2011-232503

(51) Int. Cl. B24B 7/22; H01L 29/24

(52) U.S. Cl. 257/77; 451/41; 257/E29.104

(57) ABSTRACT

A method of manufacturing a silicon carbide substrate includes the steps of preparing an ingot composed of single crystal silicon carbide, obtaining a silicon carbide substrate by slicing the ingot, and polishing a surface of the silicon carbide substrate. In the step of obtaining a silicon carbide substrate, the ingot is sliced such that cutting proceeds in a direction in which an angle formed with respect to a <11-20> direction or a <1-100> direction is 15±5° in an orthogonal projection on a {0001} plane. In the step of polishing a surface of the silicon carbide substrate, at least one of main surfaces of the silicon carbide substrate is polished while the entire surface of at least one of the main surfaces of the silicon carbide substrate is in contact with a polishing surface.

### BACKGROUND OF THE INVENTION

1. Field of the Invention

The present invention relates to a method of manufacturing a silicon carbide substrate and a silicon carbide substrate, and more particularly to a method of manufacturing a silicon carbide substrate capable of suppressing warpage and variation in plane orientation at a main surface and a silicon carbide substrate allowing manufacturing of a high-quality semiconductor device.

2. Description of the Background Art

In recent years, in order to achieve a higher breakdown voltage and lower loss of a semiconductor device, use thereof in an environment at high temperature and the like, silicon carbide has increasingly been adopted as a material for forming a semiconductor device. Silicon carbide is a wide band-gap semiconductor greater in band gap than silicon conventionally widely used as a material for forming a semiconductor device. Therefore, by adopting silicon carbide as a material for forming a semiconductor device, a higher breakdown voltage, a lower ON resistance of a semiconductor device and the like can be achieved. In addition, a semiconductor device adopting silicon carbide as a material is also more advantageous than a semiconductor device adopting silicon as a material in that deterioration in its characteristics at the time when it is used in an environment at high temperature is less.

A semiconductor device including silicon carbide as a material is manufactured, for example, by forming an epitaxial growth layer on a silicon carbide substrate, fabricating a region therein, in which a desired impurity has been introduced, and forming an electrode. Here, in order to form a high-quality epitaxial growth layer, a silicon carbide substrate uniform in plane orientation at a main surface should be used. To that end, for example, Japanese Patent Laying-Open No. 2001-294499 has proposed obtaining of a silicon carbide substrate uniform in plane orientation at a main surface by controlling a temperature condition during crystal growth or a crystal shape, and the like.

The silicon carbide substrate proposed in Japanese Patent Laying-Open No. 2001-294499 is uniform in plane orientation at the main surface, whereas it is great in warpage of the substrate and in variation in thickness. Though warpage of the substrate can be lessened by surface polishing or the like, planarization of a surface of the substrate great in warpage by polishing or the like will cause variation in plane orientation at the polished main surface.

### SUMMARY OF THE INVENTION

The present invention was made in view of the problems above and its object is to provide a method of manufacturing a silicon carbide substrate capable of suppressing warpage and variation in plane orientation at a main surface and a silicon carbide substrate allowing manufacturing of a high-quality semiconductor device.

A method of manufacturing a silicon carbide substrate according to the present invention includes the steps of preparing an ingot composed of single crystal silicon carbide and having a diameter not smaller than 2 inches, obtaining a substrate by slicing the ingot, and polishing a surface of the substrate. In the step of obtaining a substrate, the ingot is sliced such that cutting proceeds in a direction in which an angle formed with respect to a <11-20> direction or a <1-100> direction is 15±5° in an orthogonal projection on a {0001} plane. In the step of polishing a surface of the substrate, at least one main surface of the substrate is polished while the entire surface of the at least one main surface of the substrate is in contact with a polishing surface.

Here, a state where the entire main surface of the substrate is in contact with the polishing surface means such a state that the main surface of the substrate is in contact with the polishing surface substantially over the entire region as a result of correction of warpage or waving of the substrate, and it encompasses not only such a state that the entire main surface of the substrate is completely in contact with the polishing surface in all regions but also such a state that a part of the main surface of the substrate is distant from the polishing surface. In addition, the polishing surface refers to a surface at which polishing proceeds with the surface being in contact with the main surface of the substrate, and for example, to a surface of a grindstone, a surface of a surface plate, or the like.

The present inventor has conducted detailed studies about approaches for suppressing warpage and variation in plane orientation at the main surface of the substrate composed of silicon carbide. Consequently, firstly, the present inventor has found that warpage of the substrate is suppressed by causing slicing to proceed in a direction at a certain angle with respect to a direction of cleavage of crystal of silicon carbide in a phase of cutting an ingot composed of single crystal silicon carbide. If a substrate where warpage still remains is polished without any measures being taken, however, polishing proceeds while a state of curving of a crystal plane is maintained and hence variation in plane orientation at the polished main surface is caused. In contrast, the studies conducted by the present inventor have revealed that warpage of the substrate can further be lessened with variation in plane orientation at at least one main surface being suppressed, by polishing the substrate while the entire surface of at least one main surface of the substrate is in contact with the polishing surface.

In the method of manufacturing a silicon carbide substrate according to the present invention, by causing slicing to proceed in such a direction that an angle formed with respect to the <11-20> direction or the <1-100> direction, which is a direction of cleavage of crystal of silicon carbide, is 15°±5° in an orthogonal projection on the {0001} plane, a substrate of which warpage is suppressed can be obtained. Then, the obtained substrate is polished while the entire surface of at least one main surface is in contact with the polishing surface. Therefore, warpage of the substrate can further be lessened while variation in plane orientation at at least one main surface of the substrate is suppressed. Thus, according to the method of manufacturing a silicon carbide substrate in the present invention, warpage and variation in plane orientation at the main surface of the substrate can be suppressed.

In the method of manufacturing a silicon carbide substrate above, in the step of obtaining a substrate, the ingot may be sliced such that an off angle with respect to the {0001} plane of the at least one main surface is not smaller than 50° and not greater than 80°. Thus, warpage of the obtained substrate can more effectively be suppressed.

In the method of manufacturing a silicon carbide substrate above, in the step of polishing a surface of the substrate, opposing main surfaces of the substrate may be polished while the entire surfaces of the opposing main surfaces of the substrate are in contact with the polishing surfaces. By doing so, the surface of the substrate can efficiently be polished.

In the method of manufacturing a silicon carbide substrate above, the step of polishing a surface of the substrate may include the steps of correcting the substrate such that the entire surfaces of the opposing main surfaces of the substrate are in contact with the polishing surfaces and polishing the opposing main surfaces of the corrected substrate. In addition, in the step of polishing the opposing main surfaces of the corrected substrate, the opposing main surfaces may be polished while loose abrasive grains in an amount greater than in the step of correcting the substrate are supplied.

Thus, as the opposing main surfaces of the substrate are polished with a large amount of loose abrasive grains being supplied after correction of the substrate such that the entire surfaces of the opposing main surfaces of the substrate are in contact with the polishing surfaces, a polishing rate improves after completion of correction and hence variation in plane orientation at the main surface of the substrate can more reliably be suppressed.

In the method of manufacturing a silicon carbide substrate above, in the step of polishing a surface of the substrate, the other main surface different from the one main surface of the substrate may be fixed to be in contact with a flat surface of a holding member. Then, the one main surface of the substrate may be polished while the entire surface of the one main surface of the substrate is in contact with the polishing surface.

Thus, the entire surface of the one main surface of the substrate can reliably be polished. Consequently, variation in plane orientation at the one main surface of the substrate can be suppressed.

The method of manufacturing a silicon carbide substrate above may further include the step of checking a state of fixing of the substrate before the step of polishing a surface of the substrate.

Thus, the entire surface of the one main surface of the substrate can more reliably be polished. Consequently, variation in plane orientation at the one main surface of the substrate can more reliably be suppressed.

A silicon carbide substrate according to the present invention has a diameter not smaller than 2 inches. In addition, SORT in a central region which is a region extending by at most 1 inch from a center of at least one main surface is not greater than 30 μm. Moreover, variation in peak position of X-ray diffraction in the central region is not greater than 0.3°.

Since variation in plane orientation at the main surface and warpage of the silicon carbide substrate according to the present invention are suppressed, an epitaxial growth layer having high crystallinity can readily be formed on the main surface. Therefore, with the silicon carbide substrate according to the present invention, a high-quality semiconductor device can be manufactured.

In the silicon carbide substrate above, variation in peak position of X-ray diffraction in a region excluding a region extending by 2 mm from an outer circumference may be not greater than 0.3°.

Thus, an epitaxial growth layer having high crystallinity can more readily be formed on the main surface of the silicon carbide substrate above.

As is clear from the description above, according to the method of manufacturing a silicon carbide substrate and the silicon carbide substrate in the present invention, a method of manufacturing a silicon carbide substrate capable of suppressing warpage and variation in plane orientation at the main surface and a silicon carbide substrate allowing manufacturing of a high-quality semiconductor device can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart schematically showing a method of manufacturing a silicon carbide substrate.

FIGS. 2 to 6 are schematic diagrams for illustrating the method of manufacturing a silicon carbide substrate.

FIG. 7 is a schematic diagram showing a silicon carbide substrate.

FIG. 8 is a flowchart schematically showing a method of manufacturing a silicon carbide substrate according to a second embodiment.

FIGS. 9 and 10 are schematic diagrams for illustrating the method of manufacturing a silicon carbide substrate according to the second embodiment.

### DESCRIPTION OF THE PREFERRED EMBODIMENTS

An embodiment of the present invention will be described hereinafter with reference to the drawings. It is noted that, in the drawings below, the same or corresponding elements have the same reference characters allotted and description thereof will not be repeated. In addition, an individual orientation, a collective orientation, an individual plane, and a collective plane are herein shown in [ ], < >, ( ) and { }, respectively. Moreover, in terms of crystallography, a negative index should be denoted by a number with a bar “−” thereabove, however, a negative sign herein precedes a number.

### First Embodiment

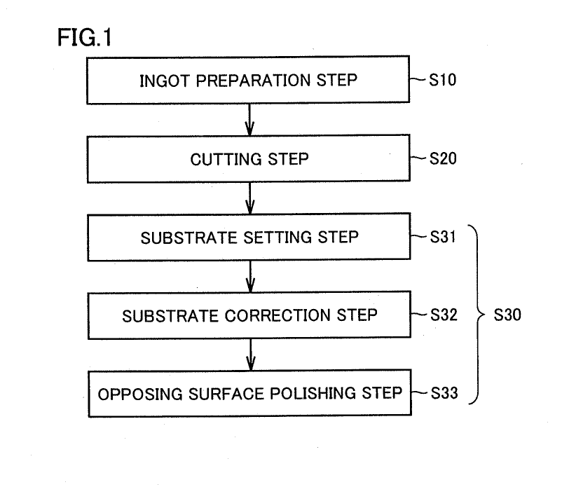

Initially, a method of manufacturing a silicon carbide substrate and a silicon carbide substrate according to a first embodiment which is one embodiment of the present invention will be described. Firstly, a method of manufacturing a silicon carbide substrate according to the present embodiment will be described with reference to FIGS. 1 to 6. Referring to FIG. 1, in the method of manufacturing a silicon carbide substrate according to the present embodiment, initially, as a step (S10), an ingot preparation step is performed. In this step (S10), for example with a sublimation method described below, an ingot composed of single crystal silicon carbide and having a diameter not smaller than 2 inches is fabricated.

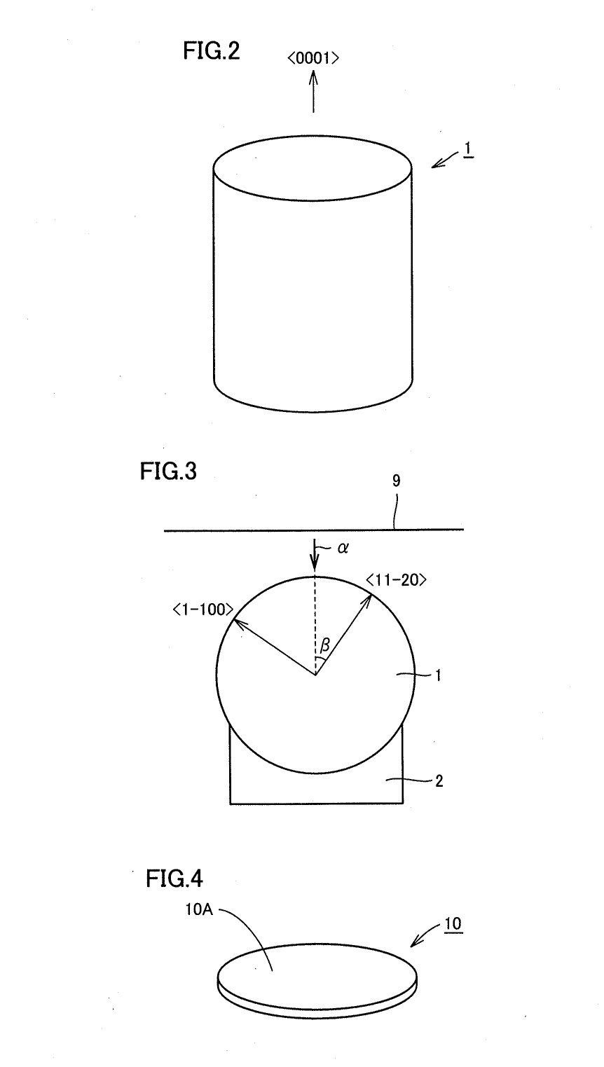

Initially, a seed crystal composed of single crystal silicon carbide and source material powders composed of silicon carbide are placed in a container composed of graphite. Then, silicon carbide sublimates as the source material powders are heated and silicon carbide is recrystallized on the seed crystal. Here, recrystallization proceeds while a desired impurity such as nitrogen is being introduced. Thus, an ingot 1 composed of single crystal silicon carbide is obtained as shown in FIG. 2. It is noted that, by setting a direction of growth of ingot 1 to the <0001> direction as shown in FIG. 2, ingot 1 can efficiently be fabricated.

Then, as a step (S20), a cutting step is performed. In this step (S20), referring to FIGS. 3 and 4, a silicon carbide substrate 10 is obtained by slicing fabricated ingot 1. Specifically, initially, ingot 1 is set such that a part of a side surface thereof is supported by a support base 2. Then, a wire 9 comes closer to ingot 1 along a cutting direction a which is a direction perpendicular to a direction of running while the wire runs in a direction along a direction of a diameter of ingot 1, so that wire 9 and ingot 1 come in contact with each other. Then, as wire 9 continues to move along cutting direction α, ingot 1 is cut.

This step (S20) will more specifically be described. For example, a cutting liquid such as slurry in which single crystal diamond serving as loose abrasive grains and a cutting oil have been mixed is supplied to a region where wire 9 composed, for example, of an alloy containing iron and nickel runs in contact with ingot 1 and wire 9 and ingot 1 come in contact with each other, and thus ingot 1 is cut. Thus, ingot 1 is sliced and silicon carbide substrate 10 as shown in FIG. 4 is obtained.

In addition, in this step (S20), as shown in FIG. 3, ingot 1 is sliced such that slicing proceeds in a direction in which an angle formed with respect to the <11-20> direction or the <1-100> direction of ingot 1 is 15°±5° in an orthogonal projection on the {0001} plane. Specifically, for example as shown in FIG. 3, an angle β formed between the <11-20> direction of ingot 1 and cutting direction α is set to 15°±5°. Thus, influence on wire 9 by the cleavage direction is lessened and warpage of silicon carbide substrate 10 is suppressed. Moreover, variation in thickness of silicon carbide substrate 10 is lessened, for example, to 10 μm or less.

Furthermore, in this step (S20), ingot 1 may be sliced such that an off angle with respect to the {0001} plane of a main surface 10A of silicon carbide substrate 10 is not smaller than 50° and not greater than 80°. Thus, warpage of obtained silicon carbide substrate 10 can more effectively be suppressed.

Then, as a step (S30), a polishing step is performed. In this step (S30), opposing main surfaces of silicon carbide substrate 10 are polished as steps (S31) to (S33) described below are performed. It is noted that, as described above, though warpage of silicon carbide substrate 10 obtained by slicing ingot 1 in the step (S20) is suppressed, it has not yet completely been eliminated. Therefore, by polishing opposing main surfaces of silicon carbide substrate 10 in this step (S30), warpage of silicon carbide substrate 10 is further lessened.

Initially, as a step (S31), a substrate setting step is performed. In this step (S31), referring to FIG. 5, initially, silicon carbide substrate 10 is set on a lower surface plate 30 having a polishing surface 30A composed, for example, of copper such that a part of main surface 10A is in contact with polishing surface 30A. Then, an upper surface plate 40 having a polishing surface 40A composed, for example, of copper is set on silicon carbide substrate 10 such that polishing surface 40A is in contact with a part of a main surface 10B. Thus, silicon carbide substrate 10 is arranged to lie between lower surface plate 30 and upper surface plate 40. It is noted that lower surface plate 30 and upper surface plate 40 may be not only a surface plate having polishing surfaces 30A, 40A composed of copper as described above but also a surface plate on which surface a grindstone having abrasive grains composed of a material higher in hardness than silicon carbide such as diamond fixed is arranged.

Then, as a step (S32), a substrate correction step is performed. In this step (S32), referring to FIG. 6, upper surface plate 40 is operated in a direction approaching lower surface plate 30 while lower surface plate 30 and upper surface plate 40 are rotated relative to each other. Thus, as shown in FIG. 6, entire main surfaces 10A, 10B of silicon carbide substrate 10 are in contact with respective polishing surfaces 30A, 40A. In addition, in this step (S32), supply of a working liquid 60 through a supply pipe 50 in between polishing surface 30A and polishing surface 40A is started. Working liquid 60 may be a cutting oil or the like for readily causing polishing of main surfaces 10A, 10B to proceed, and it may contain loose abrasive grains composed, for example, of diamond, and the like.

Then, as a step (S33), an opposing surface polishing step is performed. In this step (S33), entire main surfaces 10A, 10B of silicon carbide substrate 10 are polished while entire main surfaces 10A, 10B are in contact with respective polishing surfaces 30A, 40A and working liquid 60 containing loose abrasive grains greater in amount than in the step (S32) is supplied through supply pipe 50.

Though change in amount of supply of loose abrasive grains between the step (S32) and the step (S33) is not essential in the method of manufacturing a silicon carbide substrate according to the present invention, by doing so, a polishing rate improves after completion of correction of silicon carbide substrate 10, and therefore variation in plane orientation at main surfaces 10A, 10B of silicon carbide substrate 10 can more reliably be suppressed.

Thus, in the step (S30) above, main surfaces 10A, 10B are polished with silicon carbide substrate 10 having been corrected such that entire main surfaces 10A, 10B of silicon carbide substrate 10 are in contact with respective polishing surfaces 30A, 40A, and thus variation in plane orientation at main surfaces 10A, 10B of silicon carbide substrate 10 can more reliably be suppressed. As the steps (S10) to (S30) above are performed, silicon carbide substrate 10 is manufactured and the method of manufacturing a silicon carbide substrate according to the present embodiment is completed.

Then, a silicon carbide substrate according to the present embodiment will be described. Silicon carbide substrate 10 according to the present embodiment is manufactured, for example, with the method of manufacturing a silicon carbide substrate according to the present embodiment above.

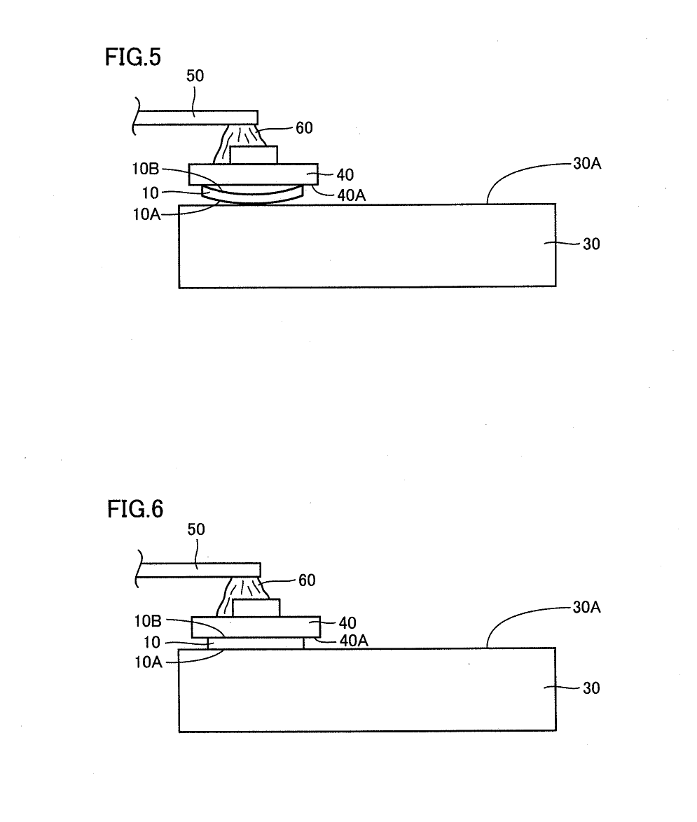

Silicon carbide substrate 10 has a diameter not smaller than 2 inches. In addition, referring to FIG. 7, SORI in a central region A which is a region in silicon carbide substrate 10, extending by 1 inch or less from the center of main surface 10A, 10B, is not greater than 30 μm. Moreover, variation in peak position of X-ray diffraction in central region A is not greater than 0.3°.

Thus, since warpage and variation in plane orientation at main surfaces 10A, 10B of silicon carbide substrate 10 according to the present embodiment are suppressed, an epitaxial growth layer high in crystallinity can readily be formed on main surface 10A, 10B. Therefore, with silicon carbide substrate 10 according to the present embodiment, a high-quality semiconductor device can be manufactured.

In addition, in silicon carbide substrate 10 according to the present embodiment above, more preferably, variation in peak position of X-ray diffraction is not greater than 0.3° in a region B excluding a region extending by 2 mm from an outer circumference. Thus, an epitaxial growth layer high in crystallinity can more readily be formed on main surface 10A, 10B of silicon carbide substrate 10.

### Second Embodiment

A method of manufacturing a silicon carbide substrate and a silicon carbide substrate according to a second embodiment which is another embodiment of the present invention will now be described. The method of manufacturing a silicon carbide substrate according to the present embodiment is performed basically similarly to the method of manufacturing a silicon carbide substrate according to the first embodiment above and achieves a similar effect. In addition, the silicon carbide substrate according to the present embodiment is basically similar to that in the first embodiment above and achieves a similar effect. The method of manufacturing a silicon carbide substrate according to the present embodiment, however, is different from the method of manufacturing a silicon carbide substrate according to the first embodiment above in that one main surface rather than opposing main surfaces of a silicon carbide substrate is polished.

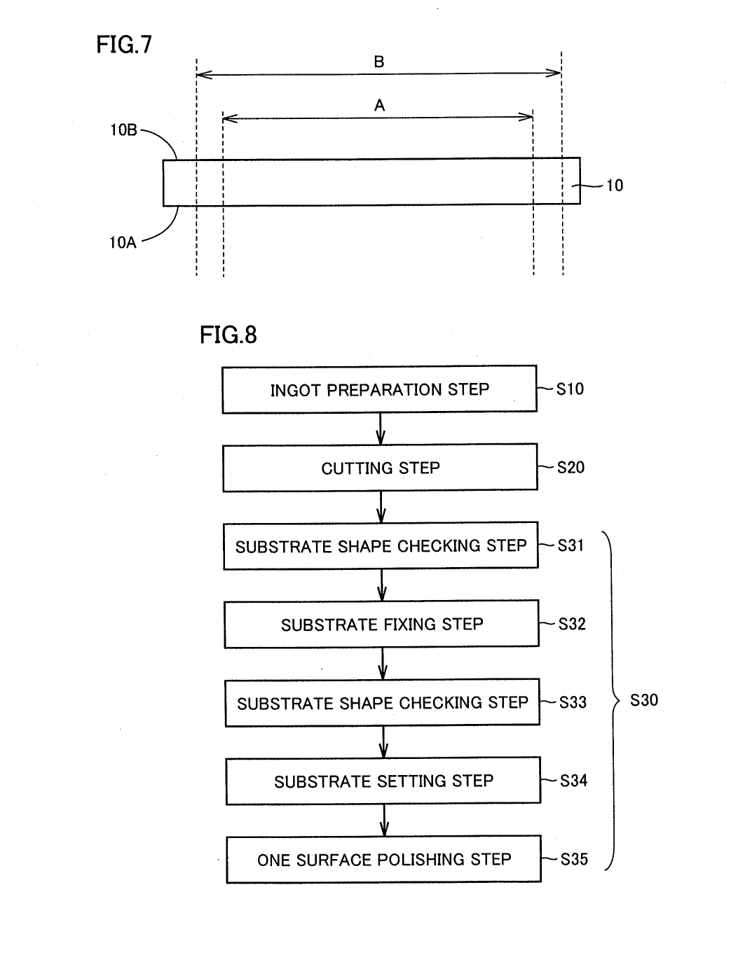

The method of manufacturing a silicon carbide substrate according to the present embodiment will be described hereinafter with reference to FIGS. 8 to 10. Referring to FIG. 8, initially, as the step (S10), the ingot preparation step is performed. In this step (S10), as in the first embodiment, ingot 1 composed of single crystal silicon carbide and having a diameter not smaller than 2 inches is fabricated.

Then, as the step (S20), the cutting step is performed. In this step (S20), as in the first embodiment, silicon carbide substrate 10 is obtained by slicing ingot 1.

Then, as the step (S30), the polishing step is performed. This step (S30) includes steps (S31) to (S35) described below and the entire one main surface of silicon carbide substrate 10 is polished.

Initially, as a step (S31), a substrate shape checking step is performed. In this step (S31), for example, a thickness of silicon carbide substrate 10 is measured at any 5 points in the main surface of silicon carbide substrate 10.

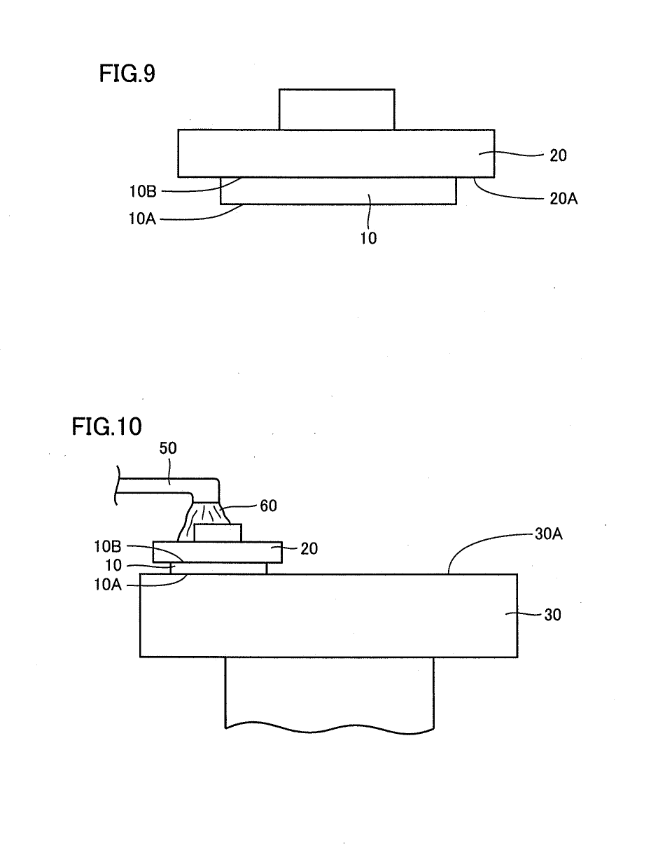

Then, as a step (S32), a substrate fixing step is performed. In this step (S32), referring to FIG. 9, silicon carbide substrate 10 of which thickness has been checked in the step (S31) is fixed to a holding member 20. Specifically, with the use of such an adhesive as wax, silicon carbide substrate 10 is fixed to holding member 20 such that main surface 10B different from main surface 10A to be polished is in contact with a flat surface 20A of holding member 20.

Then, as a step (S33), a substrate shape checking step is performed. In this step (S33), after silicon carbide substrate 10 is fixed to holding member 20 as described above, a thickness of silicon carbide substrate 10 is measured at positions the same as any 5 points at which a thickness was measured in the step (S31). Thus, accuracy in fixing of silicon carbide substrate 10 to holding member 20 is checked. In the present embodiment, silicon carbide substrate 10 is fixed to holding member 20 with accuracy of fixing not more than 5

Then, as a step (S34), a substrate setting step is performed. In this step (S34), referring to FIG. 10, silicon carbide substrate 10 fixed to holding member 20 is set on lower surface plate 30 such that entire main surface 10A to be polished is in contact with polishing surface 30A.

Then, as a step (S35), a one surface polishing step is performed. In this step (S35), entire main surface 10A is polished by rotating holding member 20 and lower surface plate 30 relative to each other while entire main surface 10A of silicon carbide substrate 10 is in contact with polishing surface 30A.

Thus, in this step (S30), as a thickness of silicon carbide substrate 10 is checked before polishing of main surface 10A of silicon carbide substrate 10, entire main surface 10A can more reliably be polished. Consequently, variation in plane orientation at main surface 10A of silicon carbide substrate 10 can more reliably be suppressed. As the steps (S10) to (S30) above are performed, silicon carbide substrate 10 is manufactured and the method of manufacturing a silicon carbide substrate according to the present embodiment is completed. It is noted that main surface 10B may be polished similarly to main surface 10A as necessary.

As described above, in the method of manufacturing a silicon carbide substrate according to the embodiment of the present invention, by causing slicing to proceed in such a direction that an angle formed with respect to the <11-20> direction or the <1-100> direction, which is a direction of cleavage of crystal of silicon carbide, is 15°±5° in an orthogonal projection on the {0001} plane, silicon carbide substrate 10 of which warpage is suppressed can be obtained. Then, obtained silicon carbide substrate 10 is polished while the entire surface of at least one main surface of main surfaces 10A, 10B is in contact with polishing surface 30A, 40A. Therefore, warpage of silicon carbide substrate 10 can further be lessened while variation in plane orientation at at least one main surface of main surfaces 10A, 10B of silicon carbide substrate 10 is suppressed. Thus, according to the method of manufacturing a silicon carbide substrate in the present invention, warpage and variation in plane orientation at the main surface of silicon carbide substrate 10 can be suppressed.

In addition, in the method of manufacturing a silicon carbide substrate according to the present invention, entire opposing main surfaces 10A, 10B of silicon carbide substrate 10 may be polished as shown in the first embodiment. By doing so, the surface of silicon carbide substrate 10 can efficiently be polished.

Moreover, in the method of manufacturing a silicon carbide substrate according to the present invention, entire main surface 10A which is one main surface of silicon carbide substrate 10 may be polished as shown in the second embodiment. Thus, entire main surface 10A of silicon carbide substrate 10 can reliably be polished. Consequently, variation in plane orientation at main surface 10A of silicon carbide substrate 10 can be suppressed.

The method of manufacturing a silicon carbide substrate and the silicon carbide substrate according to the present invention are particularly advantageously applicable to a method of manufacturing a silicon carbide substrate required to form a high-quality epitaxial growth layer on a main surface of the silicon carbide substrate and to a silicon carbide substrate.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a silicon carbide substrate, comprising the steps of:
preparing an ingot composed of single crystal silicon carbide and having a diameter not smaller than 2 inches;
obtaining a substrate by slicing said ingot; and
polishing a surface of said substrate,
in said step of obtaining a substrate, said ingot being sliced such that cutting proceeds in a direction in which an angle formed with respect to a <11-20> direction or a <1-100> direction is 15±5° in an orthogonal projection on a {0001} plane, and
in said step of polishing a surface of said substrate, at least one main surface of said substrate being polished while entire surface of said at least one main surface of said substrate is in contact with a polishing surface.

2. The method of manufacturing a silicon carbide substrate according to claim 1, wherein
in said step of obtaining a substrate, said ingot is sliced such that an off angle with respect to the {0001} plane of said at least one main surface is not smaller than 50° and not greater than 80°.

3. The method of manufacturing a silicon carbide substrate according to claim 1, wherein
in said step of polishing a surface of said substrate, opposing main surfaces of said substrate are polished while entire surfaces of the opposing main surfaces of said substrate are in contact with said polishing surfaces.

4. The method of manufacturing a silicon carbide substrate according to claim 3, wherein
said step of polishing a surface of said substrate includes the steps of
correcting said substrate such that the entire surfaces of said opposing main surfaces of said substrate are in contact with said polishing surfaces, and
polishing said opposing main surfaces of corrected said substrate, and
in said step of polishing said opposing main surfaces of corrected said substrate, said opposing main surfaces are polished while loose abrasive grains in an amount greater than in said step of correcting said substrate are supplied.

5. The method of manufacturing a silicon carbide substrate according to claim 1, wherein
in said step of polishing a surface of said substrate, the other main surface different from the one main surface of said substrate is fixed to be in contact with a flat surface of a holding member, and said one main surface of said substrate is polished while the entire surface of said one main surface of said substrate is in contact with said polishing surface.

6. The method of manufacturing a silicon carbide substrate according to claim 5, further comprising the step of checking a state of fixing of said substrate before the step of polishing a surface of said substrate.

7. A silicon carbide substrate, having
a diameter not smaller than 2 inches,
SORT not greater than 30 μm in a central region which is a region extending by at most 1 inch from a center of at least one main surface, and
variation in peak position of X-ray diffraction in said central region not greater than 0.3°.

8. The silicon carbide substrate according to claim 7, wherein
said variation in peak position of X-ray diffraction in a region excluding a region extending by 2 mm from an outer circumference is not greater than 0.3°.
